(19) United States
(12) Patent Application Publication
(10) Pub. No.: US 2022/0094322 A1
(43) Pub. Date: Mar. 24, 2022

(54) ELECTRO-ACOUSTIC RESONATOR AND METHOD FOR MANUFACTURING THE SAME

(71) Applicant: RF360 EUROPE GMBH, Munchen (DE)

(72) Inventor: Florian LOCHNER, Taufkirchen (DE)

(21) Appl. No.: 17/429,136

(22) PCT Filed: Jan. 24, 2020
(86) PCT No.: PCT/EP2020/051808

§ 371 Date: Aug. 6, 2021

(30) Foreign Application Priority Data
Feb. 25, 2019 (DE) 10 2019 104 726.9

(51) Int. Cl. H03H 9/02; H03H 3/02; H03H 9/13; H03H 9/17; H03H 9/56

(52) U.S. Cl. CPC H03H 9/02118; H03H 3/02; H03H 9/02031; H03H 9/131; H03H 2003/025; H03H 9/176; H03H 9/562; H03H 9/564; H03H 9/568; H03H 9/175

(57) ABSTRACT

An electro-acoustic resonator comprises an acoustic mirror (120) disposed on a carrier substrate (110), a bottom electrode (130) and a piezoelectric layer (140). An aluminum seed layer (180) is disposed on the piezoelectric layer and a structured silicon dioxide flap layer (150) is disposed on the aluminum seed layer. The aluminum seed layer (180) increases the quality factor of the resonator and leads to enhanced RF filter performance.

### TECHNICAL FIELD

The present disclosure relates to an electro-acoustic resonator. Specifically, the present disclosure relates to an electro-acoustic resonator that comprises a piezoelectric layer sandwiched between bottom and top electrodes. The present disclosure also relates to a method to manufacture such an electro-acoustic resonator. The present disclosure also relates to a RF filter that includes several resonators.

### BACKGROUND

Electro-acoustic resonators are widely used in electronic devices to perform frequency selective functions. A bulk acoustic wave (BAW) resonator comprises a piezoelectric layer sandwiched between bottom and top electrodes. An electrical signal applied to the electrodes generates a resonating acoustic wave within the piezoelectric layer that is frequency selective to the electrical signal. A RF filter that includes several electro-acoustic resonators may be used in communication equipment to select the wanted signal from the received signal spectrum or shape the to be transmitted spectrum.

A dielectric layer disposed on the piezoelectric layer surrounding the acoustically active area generates a step feature on the surface of the piezoelectric layer to substantially confine the acoustic energy within the active area and prevent the acoustic wave from escaping from the active area.

A RF filter that includes an arrangement of multiple BAW resonators in a ladder type structure may be specifically used in state of the art communication services such as the 4G (LTE) communication standard. As the manufacturers of communication equipment always seek to improve the quality of their devices, there is a need to improve the passband characteristics of the RF filters, for example, increase the transmission or reduce the attenuation within the passband portion of a RF filter. Even a moderate step of improvement of the filter performance is welcome to the communication equipment manufacturer. Accordingly, there is a need to improve the quality factor of a BAW resonator and improve the passband performance of a RF filter.

It is object of the present disclosure to provide an electro-acoustic resonator of the bulk acoustic wave type that exhibits an improved quality factor.

It is another object of the present disclosure to provide a method for manufacturing an electro-acoustic resonator that exhibits an improved quality factor.

It is yet another object of the present disclosure to provide a RF filter with improved passband performance.

### SUMMARY

An electro-acoustic resonator that achieves one or more of the above-mentioned objects comprises the features of present claim 1.

According to embodiments, an electro-acoustic resonator comprises a carrier substrate and an acoustic mirror disposed thereon. A sandwich of a bottom electrode, a piezoelectric layer and a top electrode is disposed on the acoustic mirror forming an acoustically active area in the overlap region of bottom and top electrodes. A silicon dioxide layer is disposed on portions of the piezoelectric layer. A seed layer of aluminum is disposed between the piezoelectric layer and the silicon dioxide layer. The silicon dioxide layer is structured and surrounds the acoustically active area, wherein the portion of the silicon dioxide layer in the active area has been removed.

Using an aluminum seed layer for a subsequent deposition of the silicon dioxide layer, the electro-acoustic characteristics of the resonator are improved. It turned out that the quality factor of the electro-acoustic resonator is improved with an aluminum seed layer when compared to other seed layers such as a titanium seed layer. A RF filter using several of these resonators, for example, in a ladder type filter structure has less attenuation or insertion loss and higher transmission in the passband frequency region of the filter. The resonator with an aluminum seed layer and the structured silicon dioxide layer disposed thereon achieves a predictable and reliable performance in the filter passband region which leads to increased filter performance.

The silicon dioxide layer is deposited on the wafer having the aluminum seed layer on its top surface and is structured using masking and lithography steps to remove a portion in which the top metal electrode is formed thereafter. The aluminum seed layer may remain in the area where the silicon dioxide layer is removed so that the aluminum from the seed layer forms an etch stop for the etching of the silicon dioxide layer which may be reliably detected during the etching process. Also an overlap layer may extend into the area of the removed portion of the silicon dioxide layer. The structured silicon dioxide layer surrounds the region in which the top electrode is disposed. The structured silicon dioxide layer is often called a flap layer. One of the functions of the structured silicon dioxide layer is to confine the acoustic energy within the active area and substantially avoid that acoustic energy leaks from the active area. The structured silicon dioxide layer adds an additional mass on the piezoelectric layer that surrounds the active area so that the acoustic characteristics are changed in the region where the silicon dioxide flap is present which causes an energy confinement effect.

The top electrode as such is made of metal and may be a stack of layers. The top electrode may comprise a layer stack comprising a bottom layer opposite and adjacent to the piezoelectric layer of tungsten, a thereon disposed intermediate layer of aluminum and copper and a thereon disposed top layer of a metal nitride such as titanium nitride. The aluminum-copper layer may be formed by a sputtering technique using a AlCu target. In an example, the bottom electrode may have the same layers as the top electrode. The layer stack of the top electrode is surrounded by the structured silicon dioxide layer. The electrodes form the acoustically active area within the piezoelectric layer, where the piezoelectric layer is sandwiched by the bottom and top electrodes.

According to embodiments, an overlap layer may be disposed on the structured silicon dioxide layer. The overlap layer may extend from the top surface of the silicon dioxide layer into a portion of the acoustically active area where the silicon dioxide layer is removed. The overlap layer extends from the top surface of the silicon dioxide layer along a vertical sidewall of the silicon dioxide layer onto the piezoelectric layer within the acoustically active area. Within the acoustically active area, the metal overlap layer is disposed between the top electrode and the piezoelectric layer. The top electrode covers the active area including a portion of the flap layer and a portion of the overlap layer. The metal overlap layer may comprise a layer stack of a layer of titanium disposed on the silicon dioxide layer and a layer of tungsten disposed on the titanium layer. The top tungsten layer is removed and the bottom titanium layer of the overlap layer is maintained as an adhesion promoter for the subsequent forming of the top electrode. In this case, thin layers of aluminum and titanium remain in the active area on which the top electrode is deposited. It is also possible to remove both layers of tungsten and titanium of the overlap layer stack within a portion of the acoustically active area.

The piezoelectric layer may be made of piezoelectric aluminum nitride that may be crystalline, columnar aluminum nitride or may be made of aluminum scandium nitride. Other piezoelectric materials are also useful. The scandium portion within the aluminum scandium nitride piezoelectric layer may be in the range from 0 to about 35 weight-%. Specifically, the scandium portion may be in the range of 5 to 15 weight-%, more specifically, the scandium portion may be of 7 weight-% within the aluminum scandium nitride layer.

One or more of the above-mentioned objects are also achieved by a method comprising the features of present claim 10.

The manufacturing of an electro-acoustic resonator comprises providing a carrier substrate on which an acoustic mirror is disposed. A structured bottom electrode is formed on the acoustic mirror by depositing the layer or the layer stack of the metal bottom electrode and forming the electrode structure by masking and lithography steps. The piezoelectric layer is deposited and extends as a bulk layer on the workpiece. A relatively thin layer of aluminum is formed on the piezoelectric layer. The aluminum layer serves as a seed layer for the subsequent forming of a silicon dioxide layer. The silicon dioxide layer is formed on the aluminum seed layer and, then, a portion of the silicon dioxide layer is removed in a structuring step using masking and lithography steps in a region that is opposite the bottom electrode. The aluminum seed layer is exposed at the portion where the silicon dioxide layer is removed. A top electrode is formed on the piezoelectric layer in the region where the seed layer is exposed so that an acoustically active area is established by the layer stack of bottom electrode, piezoelectric layer and top electrode including a portion of the electrode over the flap layer.

The silicon dioxide layer may be formed by a physical vapor deposition (PVD) process. The PVD deposition may use a silicon target under an argon/oxygen atmosphere. A chemical vapor deposition (CVD) to deposit the silicon dioxide layer may also be possible. The CVD deposition process uses a TEOS gas in the reaction chamber to deposit the silicon dioxide layer on the surface of the piezoelectric layer. A silane gas instead of a TEOS precurser gas is also possible. A PVD deposited silicon dioxide layer has a higher density than a CVD deposited silicon dioxide layer so that the acoustic velocity within a PVD silicon dioxide layer is different from the acoustic velocity in the CVD silicon dioxide layer. The acoustic velocity in the PVD layer is higher than the acoustic velocity in the CVD layer. It turned out that a physically deposited silicon dioxide layer using a PVD deposition process leads to a higher quality factor of the resonator and an enhanced performance of a ladder type RF filter using said resonators when compared to resonators using a CVD silicon dioxide layer.

According to embodiments, an overlap layer is formed after the structuring of the silicon dioxide layer and before the forming of the top electrode. The overlap layer may be made of metal such as a layer stack of titanium and tungsten. At least a portion of the overlap layer is removed in a region opposite the bottom electrode, wherein another portion of the overlap layer remains in the region opposite the bottom electrode so that, after the forming of the top electrode, the overlap layer is disposed between the piezoelectric layer and the top electrode.

One or more of the above-mentioned objects are also achieved by a RF filter comprising the features of present claim 13.

The RF filter includes a series path coupled between a first and a second filter port. The series path includes a serial connection of several electro-acoustic resonators described above. One or more shunt or parallel paths are provided that are coupled between at least one of the resonators of the series path and a terminal for a reference potential such as ground potential. The shunt paths include at least one electro-acoustic resonator as described above. The RF filter exhibits a ladder type structure. The series path may comprise four serially connected resonators, wherein four shunt paths are provided. The resonators of the series and shunt paths may have different resonance frequencies. Practically, the resonators may have three different resonance frequencies. The RF filter exhibits an increased transmission within the filter passband or a reduced insertion loss or attenuation within the filter passband when compared to conventional resonators. The improvement in the filter performance is achieved with the silicon dioxide layer disposed directly on the piezoelectric layer without any intervening layer, preferably with a CVD deposition process. As an example, the filter may be a transmit (Tx) filter for the LTE band 25 which has a passband between 1.85 GHz and 1.915 GHz.

It is to be understood that both the foregoing general description and the following detailed description are merely exemplary, and are intended to provide an overview or framework to understand the nature and character of the claims. The accompanying drawings are included to provide a further understanding and are incorporated in, and constitute a part of, this description. The drawings illustrate one or more embodiments, and together with the description serve to explain principles and operation of the various embodiments. The same elements in different figures of the drawings are denoted by the same reference signs.

### BRIEF DESCRIPTION OF THE DRAWINGS

In the drawings:

FIG. 1 shows a cross-section of a portion of a bulk acoustic wave resonator;

FIG. 2 shows a schematic diagram of a RF filter; and

FIG. 3 shows a transmission diagram of the RF filter of FIG. 2.

### DETAILED DESCRIPTION OF EMBODIMENTS

The present disclosure will now be described more fully hereinafter with reference to the accompanying drawings showing embodiments of the disclosure. The disclosure may, however, be embodied in many different forms and should not be construed as limited to the embodiments set forth herein. Rather, these embodiments are provided so that the disclosure will fully convey the scope of the disclosure to those skilled in the art. The drawings are not necessarily drawn to scale but are configured to clearly illustrate the disclosure.

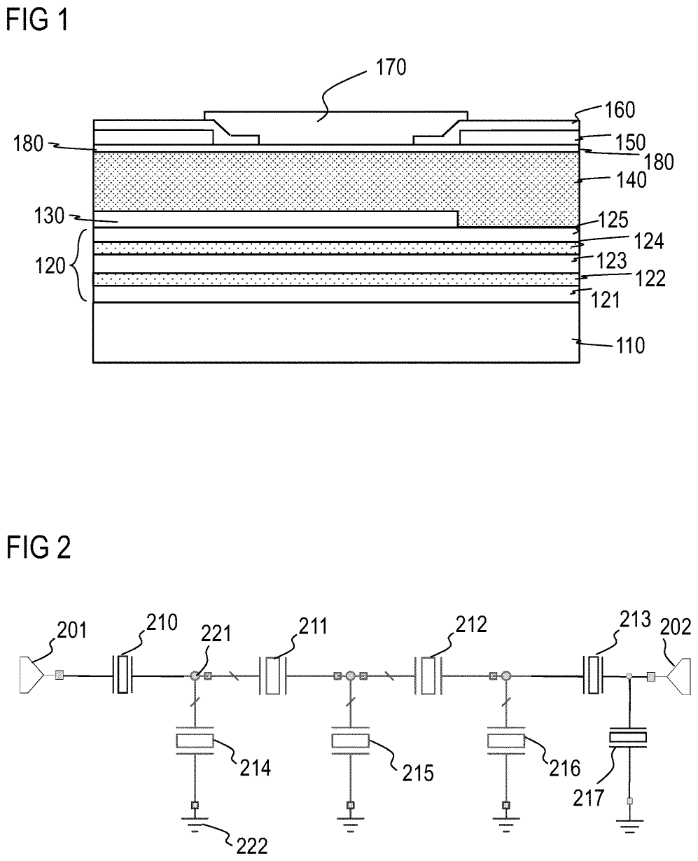

FIG. 1 depicts a cross-sectional view of a portion of a bulk acoustic wave (BAW) resonator according to the principles of the present disclosure. The resonator is of the solidly mounted resonator (SMR) type that includes an acoustic mirror such as a Bragg mirror on which an acoustically active region is disposed. In more detail, the depicted BAW resonator comprises a carrier substrate 110 such as a silicon wafer. A Bragg mirror arrangement 120 is disposed on carrier substrate 110. Bragg mirror 120 comprises a number of layers of acoustically higher impedance such as layers 122, 124 that may be made of tungsten and other layers of acoustically low impedance such as layers 121, 123, 125 that may be made of a dielectric material such as silicon dioxide. The topmost layer 125 of the Bragg mirror 120, in the present example, is made of silicon dioxide. A bottom electrode 130 is disposed on Bragg mirror 120. The electrode 130 extends on the left-hand side beyond the portion depicted in FIG. 1 to other circuit elements such as a bump contact to connect electrode 130 to other elements of the electronic circuit. A piezoelectric layer 140 is disposed on the Bragg mirror 120 and on the bottom electrode 130. Piezoelectric layer 140 may be made of aluminum scandium nitride having 7 wt % of scandium in the present example. Other piezoelectric materials such as aluminum scandium nitride with an arbitrary scandium portion or aluminum nitride or another piezoelectric material are also possible.

An aluminum layer 180 is disposed on the top surface of the piezoelectric layer 140. The aluminum layer 180 serves as a seed layer to facilitate adhesion and forming of a silicon dioxide layer thereon. A silicon dioxide layer 150 is disposed on the top surface of the piezoelectric layer 140 serving as a flap layer. The silicon dioxide flap layer 150 is structured by masking and lithography steps to form a portion in which the silicon dioxide layer 150 is removed that is opposite the bottom electrode 130 and accommodates the top electrode 170. Silicon dioxide layer 150 surrounds and encloses the removed portion in which top electrode 170 is disposed. The thickness of the silicon dioxide flap layer may be in the range of 140 nm, for example, for a resonator for a band 25 filter. The thickness may be slightly higher in the range of 150 nm to 160 nm depending on process needs. The effect of varying thickness of the silicon dioxide layer on the electro-acoustic characteristics of the resonator device are almost negligible. In a resonator for a filter according to the 5G standard, the thickness may be lower, for example, down to 20 nm. The thickness of the aluminum seed layer 180 may be in the range of 5 nm to 10 nm depending on the mass loading requirements required by the acoustic resonance conditions. In an embodiment, the thickness of the aluminum seed layer is about 8 nm or 8 nm. The mass of a 8 nm aluminum layer resembles or equals the mass of a 5 nm titanium layer which is replaced by the aluminum layer to maintain the acoustic resonance conditions. Furthermore, aluminum has a relatively high electrical conductivity. Compared to titanium, the electrical conductivity of aluminum is about 15 times higher which may reduce ohmic losses in the resonator.

According to an embodiment, the aluminum seed layer 180 is maintained even after the structuring of the silicon dioxide layer 150 so that the aluminum layer 180 is present in the area where the silicon dioxide layer has been removed. According to another embodiment, the aluminum seed layer 180 may be removed together with the silicon dioxide layer to expose the piezoelectric layer 140.

An overlap layer 160, which is made of a metal or a stack of metal layers, is disposed on silicon dioxide layer 150 and extends into the acoustically active area where a portion of silicon dioxide 150 is removed. Overlap layer 160 may comprise a bottom layer of titanium and a top layer of tungsten. Overlap 160 extends over the vertical sidewall of silicon dioxide layer 150 and contacts the top surface of aluminum layer 180. The overlap layer 160 is removed from an inner portion of the acoustically active area to allow contact between top electrode 170 and the aluminum layer 180. Specifically, the top tungsten layer of overlap 160 may be removed, wherein the bottom titanium layer of overlap 160 may be still present as a seed layer in the acoustically active area to enable proper forming of top electrode 170 within the active area. According to the other embodiment, where the aluminum layer 180 is removed in the active area, the overlay layer extends over the vertical sidewall of the silicon dioxide layer 150 and contacts the top surface of the piezoelectric layer 140.

The silicon dioxide layer 150 may be called a flap layer that covers the piezoelectric layer except the portions where an electrode contacts the piezoelectric layer 140 such as the top electrode 170 in the acoustically active area. The acoustically active area is formed in the overlap region of bottom electrode 130 and top electrode 170. By application of an electrical RF signal to the electrodes 130, 170, an acoustic resonating wave is generated within the piezoelectric layer 140 between the electrodes 130, 170. The flap layer 150 generates a step feature at its vertical sidewall which has the function of an energy confinement ring surrounding the acoustically active area so that the acoustic energy concentrated in the acoustically active area is prevented from laterally escaping therefrom into the regions of the piezoelectric substrate 140 outside of the acoustically active area and outside of the removed portion of flap layer 150.

During manufacturing of the BAW resonator depicted in FIG. 1, carrier substrate no and acoustic mirror 120 disposed thereon are provided, exposing the top dielectric layer 125 of the Bragg mirror arrangement 120. The bottom electrode layer 130 is deposited on the top layer 125 of the Bragg mirror and structured to form the bottom electrode of the acoustically active area. Then, a piezoelectric layer 140 such as an aluminum scandium nitride layer with 7 wt % of scandium is deposited. A thin aluminum layer is deposited on the top surface of the piezoelectric layer serving as a seed layer for the further deposition steps. The aluminum layer may have a thickness in the range of 8 nm. The workpiece may be transferred to another deposition chamber for silicon dioxide deposition and the process is continued with the deposition of the silicon dioxide layer 150 which may be a PVD deposition process or a CVD deposition process. During the PVD process, a silicon target is bombarded by argon ions under an oxygen atmosphere. During the CVD process, the chamber is filled with a silicon containing precurser gas such as TEOS (tetraethyl orthosilicate) through which a silicon dioxide layer is formed in a plasma process. A silane gas may also be possible. The thickness of the silicon dioxide layer is about 140 nm. Then, the silicon dioxide layer 150 is structured in that the portion of said layer opposite the bottom electrode 130 is removed to generate flap layer 150 that forms an energy confinement ring feature for the acoustic resonating wave. The aluminum seed layer is maintained in the area where the silicon dioxide layer is removed. An overlap layer 160 is deposited, wherein at least a portion of overlapping layer 160 is removed within a portion of the active area. The overlap layer 160 comprises a layer stack of a titanium layer and a tungsten layer, wherein the tungsten layer is removed and the titanium layer is maintained. In the active area, a thin double layer of aluminum from the aluminum seed layer and of titanium from the overlap layer resides. A top electrode layer 170 is deposited opposite the bottom electrode 130 to form the active area in the overlapping region of bottom and top electrodes 130, 170. The overlap layer 160 may slightly extend from the top surface of the silicon dioxide flap layer 150 along a defined amount of length into the active area underneath top electrode 170.

The etching of the silicon dioxide layer 150 to generate the flap structures may be performed through a dry etching process with suitable agents to dry etch silicon dioxide such as the gases CF₄, CHF₄, Ar, O₂. Etching is performed in a region opposite the bottom electrode 130. The etch process continues until the aluminum seed layer 180 is reached and the appearance of an aluminum component in the etch chamber may be used as an etch stop. The aluminum seed layer can be reliably detected to terminate the etching process so that etching stops safely before reaching the piezoelectric layer.

The PVD sputtering process to deposit the silicon dioxide layer 150 may, in an exemplary process, may use the following parameters:

Temperature of the substrate: 100° C.

Target power: 2.25 kW

Oxygen flow: 100 SCCM

Argon flow: 20 SCCM

Chamber pressure: 6.7 to 6.9 mTorr (0.89 Pa to 0.92 Pa).

Platen RF forward power: 325 W

The CVD chemical deposition process to deposit the silicon dioxide layer 150 may, in an exemplary process, may use the following parameters:

Chamber pressure=8.2 Torr (1.093 kPa)

Substrate temperature=390° C.

Oxygen flow=1100 SSCM

Helium flow=1200 SSCM

TEOS flow=1100 mgm (Milligramm per minute)

RF Power=680 W

The PVD or CVD deposition of the flap layer 150 is performed on the aluminum seed layer which achieves a resonator of increased quality factor, wherein it turned out that a PVD deposition is preferred over a CVD deposition since the PVD deposition renders a higher quality factor. A RF filter including several of said resonators has increased performance as explained below. Experiments showed that the quality factor of a BAW resonator using a CVD deposited silicon dioxide flap layer on an aluminum seed layer is up to 8% improved over a BAW resonator using a conventional titanium seed layer and a CVD deposited silicon dioxide flap layer and that the quality factor for a BAW resonator using a PVD deposited silicon dioxide flap layer on an aluminum seed layer is up to 4% improved over the BAW resonator using the conventional titanium seed layer under a PVD deposited silicon dioxide layer.

While the characteristics of the flap layer have been discussed above in the region of the acoustically active area where the bottom and top electrodes sandwich the piezoelectric layer, the layer stack of overlap layer, silicon dioxide flap layer and underlying seed layer and, furthermore, of top electrode and piezoelectric layer may be removed in one or more etch process steps in a region outside the active area to land on the bottom electrode. This allows forming of a contact pad on the bottom electrode and isolates resonators from each other.

FIG. 2 depicts the schematic diagram of a RF filter. The RF filter comprises a first and a second input/output port 201, 202 between which four series resonators 210, 211, 212, 213 are serially connected. The node between resonators 210, 211 is coupled to a shunt path that includes resonator 214. Resonator 214 is connected between node 221 and terminal 222 for ground potential. Other shunt paths each including a resonator 215, 216, 217 are provided between corresponding nodes of serial resonators and ground potential. The filter topology depicted in FIG. 2 is commonly known as ladder type filter. All resonators 210, . . . , 217 have the structure depicted in FIG. 1 with a flap layer 150 disposed directly on piezoelectric layer 140. According to ladder type circuit concepts, the resonators 210, . . . , 217 may have different resonance frequencies. Three different resonance frequencies are useful for the resonators of the ladder type filter of FIG. 2.

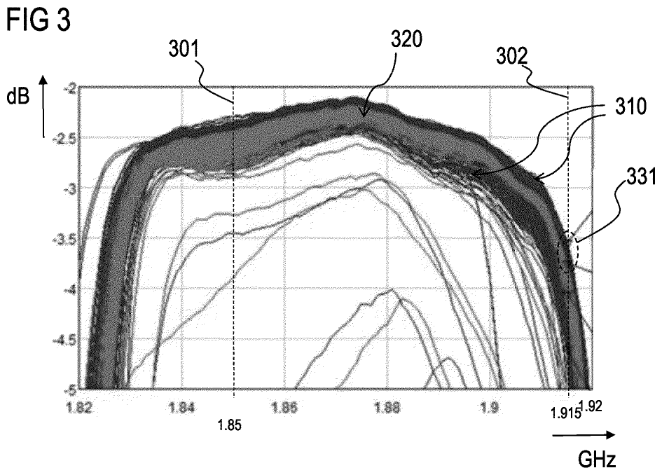

The filter of FIG. 2 may be dimensioned such that it forms a passband for band 25 as depicted in FIG. 3. The uplink (Tx) passband of band 25 has a lower edge 301 at 1.85 GHz and an upper edge 302 at 1.915 GHz. The diagram in FIG. 3 shows a variety of transmission curves 320 from RF filters with comparative resonators which exhibit a 5 nm thick titanium seed layer between the piezoelectric layer and the 140 nm thick CVD deposited silicon oxide flap layer and a variety of transmission curves 310 from RF filters with BAW resonators according to the principles of the present disclosure described in connection with FIG. 1 which include a 140 nm thick CVD-deposited silicon dioxide layer with an 8 nm thick aluminum seed layer below the silicon dioxide layer. The curves depicted in FIG. 3 are based on actual measurements from RF filters with resonators disposed on wafers from the same manufacturing lot. The different curves may result from natural non-uniformity variations across the wafer and between different wafers of the lot.

As can be gathered from FIG. 3, the RF filter with BAW resonators according to principles of the present disclosure shows transmission curves 310 disposed above at least a portion of the transmission curves 320 according to the comparative RF filter. In the lower portion of the passband, e.g., from 1.85 GHz to about 1.88 GHz, at least a portion of the measured transmission curves 310 are above the comparative transmission curves 320. In the upper portion of the passband, e.g., from 1.88 GHz to 1.915 GHz, at least a portion of the transmission curves 310 are significantly located above the comparative transmission curves 320, although the variation of the transmission curves 310 is larger than the variation of the comparative transmission curves including also curves 310 below curves 320.

At the upper edge of the passband at 1.915 GHz, which is a critical portion for the performance of a RF filter, the minimum attenuation achieved with comparative curves 320 is at about 3.745 dB, whereas the minimum attenuation achieved with curves 310 according to the principles of this disclosure is at about −3.54 dB which is an improvement of 0.205 dB, about 5.5%

It will be apparent to those skilled in the art that various modifications and variations can be made without departing from the spirit or scope of the disclosure as laid down in the appended claims. Since modifications, combinations, sub-combinations and variations of the disclosed embodiments incorporating the spirit and substance of the disclosure may occur to the persons skilled in the aft, the disclosure should be construed to include everything within the scope of the appended claims.

1. An electro-acoustic resonator, comprising:
a carrier substrate,
an acoustic mirror disposed on the carrier substrate;
a bottom electrode disposed on the acoustic mirror;
a piezoelectric layer disposed on the bottom electrode;
a seed layer comprising aluminum disposed on the piezoelectric layer;
a structured silicon dioxide layer disposed on the seed layer; and
a top electrode disposed on the piezoelectric layer.

2. The electro-acoustic resonator according to claim 1, wherein the structured silicon dioxide layer surrounds a region in which the top electrode is disposed.

3. The electro-acoustic resonator according to claim 1, wherein the structured silicon dioxide layer surrounds a region in which the silicon dioxide layer is removed and in which the top electrode is disposed.

4. The electro-acoustic resonator according to claim 1, wherein the top electrode comprises a layer stack comprising a bottom layer of tungsten, an intermediate layer of a composition of aluminum and copper and a top layer of a metal nitride.

5. The electro-acoustic resonator according to claim 1, further comprising a metal overlap layer disposed on the structured silicon dioxide layer and extending underneath a portion of the top electrode layer, wherein the metal overlap layer is disposed between the top electrode and the piezoelectric layer at said portion.

6. The electro-acoustic resonator according to claim 5, wherein the metal overlap layer comprises a layer stack of titanium and tungsten.

7. The electro-acoustic resonator according to claim 1, wherein the piezoelectric layer comprises one of aluminum nitride and aluminum scandium nitride.

8. The electro-acoustic resonator according to claim 1, wherein the seed layer consists of aluminum and the thickness of the seed layer is in the range of 5 nm to 10 nm or the thickness of the seed layer is 8 nm.

9. The electro-acoustic resonator according to claim 1, wherein the piezoelectric layer comprises aluminum scandium nitride having a scandium portion at most 35 weight-% or of 5 weight-% to 15 weight-% or of 7 weight-%.

10. A method for manufacturing an electro-acoustic resonator, comprising:
providing a carrier substrate and an acoustic mirror disposed on the carrier substrate;
forming a structured bottom electrode on the acoustic mirror;
forming a piezoelectric layer on the bottom electrode;
forming a seed layer comprising aluminum on the piezoelectric layer;
forming a layer of silicon dioxide on the seed layer;
removing a portion of the silicon dioxide layer in a region opposite the bottom electrode thereby exposing the seed layer;
forming a top electrode in the region of the exposed seed layer.

11. The method according to claim 10, wherein the step of forming a layer of silicon dioxide comprises depositing the layer of silicon dioxide on an aluminum seed layer by physical vapor deposition subjecting a silicon target to an atmosphere containing oxygen.

12. The method according to claim 10, after the step of removing a portion of the silicon dioxide layer and before the step of forming a top electrode, performing a step of forming an overlap layer made of metal and removing a portion of the overlap layer in a region opposite the bottom electrode so that the overlap layer is disposed between the top electrode and the seed layer in a region where the portion of the silicon dioxide layer is removed.

13. A radio frequency (RF) filter, comprising:
a first and a second port;
a series path coupled between the first and second ports, the series path comprising a serial connection of a plurality of electro-acoustic resonators; and
one or more shunt paths coupled to at least one of the plurality of resonators of the series path, the one or more shunt paths each including at least one electro-acoustic resonator.
